(19) United States
(12) Patent Application Publication
(10) Pub. No.: US 2017/0218267 A1
(43) Pub. Date: Aug. 3, 2017

(54) GARNET-TYPE FLUORESCENT POWDER, PREPARATION METHOD AND DEVICES COMPRISING THE FLUORESCENT POWDER

(71) Applicants: GRIREM ADVANCED MATERIALS CO., LTD., Beijing (CN); GENERAL RESEARCH INSTITUTE FOR NONFERROUS METALS, Beijing (CN)

(72) Inventors: Weidong Zhuang, Beijing (CN); Jiyou Zhong, Beijing (CN); Ronghui Liu, Beijing (CN); Yanfeng Li, Beijing (CN); Yuanhong Liu, Beijing (CN); Huibing Xu, Beijing (CN); Lei Chen, Beijing (CN)

(21) Appl. No.: 15/321,956

(22) PCT Filed: Aug. 3, 2015
(86) PCT No.: PCT/CN2015/085962

§ 371 Date: Dec. 23, 2016

(30) Foreign Application Priority Data
Oct. 15, 2014 (CN) 201410546588.0

(51) Int. Cl. C09K 11/77; C30B 29/22; C30B 1/10; H01L 33/50

(52) U.S. Cl. CPC C09K 11/7792; H01L 33/505; H01L 33/502; C09K 11/7769; C09K 11/7718; C09K 11/7721; C09K 11/7774; C30B 29/22; C30B 1/10

(57) ABSTRACT

The application relates to fluorescent powder which has a garnet structure and can be effectively excited by ultraviolet light or blue light, a method for preparing the fluorescent powder, and a light emitting device, an image display device and an illumination device comprising the fluorescent powder. A chemical formula of the fluorescent powder is expressed as: (M¹a-xM²x)ZrbM³cOd, where M¹ is one or two elements selected from Sr, Ca, La, Y, Lu and Gd, Ca or Sr being necessary; M² is one or two elements selected from Ce, Pr, Sm, Eu, Tb and Dy, Ce being necessary; M³ is at least one element selected from Ga, Si, and Ge, Ga being necessary; and 2.8≦a≦3.2, 1.9≦b≦2.1, 2.8≦c≦3.2, 11.8≦d≦12.2, and 0.002≦x≦0.6.

### CROSS-REFERENCE TO RELATED PATENT APPLICATIONS

This patent application is a United States national phase patent application based on PCT/CN2015/085962 filed Aug. 3, 2015, which claims the benefit of Chinese Patent Application No. 201410546588.0 filed Oct. 15, 2014, the disclosures of which are hereby incorporated herein by reference in their entirety.

### TECHNICAL FIELD

The application relates to the field of inorganic Light Emitting Diode (LED) luminous materials, particularly to a fluorescent powder, and more particularly to a fluorescent powder having a garnet structure. The fluorescent powder is effectively excitable by ultraviolet light or blue light to emit visible light. The application also relates to a method for preparing the fluorescent powder, and a light emitting device, an image display device and an illumination device comprising the fluorescent powder.

### BACKGROUND

An LED has the advantages of high light emitting efficiency, low power consumption, long life, low pollution, small size, high operation reaction speed and the like, and is widely applied to the fields of illumination, display and the like, wherein YAG:Ce³⁺ (Y₃Al₅O₁₂:Ce³⁺) yellow powder matches a blue-light LED chip to achieve white light, has the characteristics of high efficiency, low cost, simple manufacture and the like, and is thus widely adopted. An important reason lies in YAG yellow powder having a garnet structure has extremely stable physical and chemical properties and incomparable high light efficiency. Thus, the research and development of fluorescent powder having a garnet structure will always be the research hot focus at home and abroad. Particularly, a Ce³⁺ ion having a d-f transition serves as an activating agent, and an excitation spectrum presented thereby in the garnet structure has very strong excitation peaks in an ultraviolet area and a blue-light area separately, and can well match ultraviolet, near-ultraviolet or blue-light chips.

The synthetic temperature of a garnet structure compound such as YAG (and YAG doped with Ga, La, Lu, Gd and other elements) and Ca₃Sc₂Si₃O₁₂ is usually more than 1,500° C. Reduction of the synthetic temperature can reduce the cost, and the effects of energy conservation and emission reduction are obvious. Therefore, searching for garnet-type fluorescent powder capable of being synthesized at a low temperature plays an important role in promoting energy conservation and emission reduction and improving the level of ecological civilization.

The general formula of the garnet structure is A₃B₂(XO₄)₃, where A, B and X usually refer to octa-coordination, hexa-coordination, and tetra-coordination; and B and an adjacent atom O form an octahedron usually, and X and the adjacent atom O form a tetrahedron usually. B-site elements of a garnet structure compound doped with rare-earth elements and taken as fluorescent powder are classified, and there are divalent metal elements (such as a non-patent document 1, Mg in Lu₂CaMg₂(Si,Ge)₃O₁₂), trivalent metal elements (such as the patent document 1, Al in YAG; a patent document 2, Sc in Ca₃Sc₂Si₃O₁₂), and pentavalent metal elements (such as a patent document 3, Ta in Li₅La₂Ta₂O₁₂), usually; and the B-site elements are compounds Ca₂LaZr₂Ga₃O₁₂ of a tetravalent metal element Zr (such as the non-patent document 2), and solid solution of rare-earth elements as fluorescent powder is not reported yet. In addition, on the basis of this series of garnet structure compounds, Ga is partially replaced with tetravalent metal elements, such that the usage of Ga and the usage of lanthanide elements may be reduced to obtain new compounds such as Ca₃Zr₂Ga₂SiO₁₂, Ca₃Zr₂Ga₂GeO₁₂ and the like, and the synthetic temperatures of this series of compounds and the new compounds obtained by doping with the rare-earth elements are within 1,400° C.

In the conventional, a minority of Zr-comprising garnet structure compounds exists. According to crystallography sites occupied by Zr, these compounds are mainly divided into three classes:
the first class is representative of Ca₃Sc₂Si₃O₁₂ in a patent document 3, wherein Zr serving as a small number of doped elements partially replaces Si, Ge and other elements located in the site X;
the second class is that Zr occupies the site B, for example, Ca—Zr in patent documents 4 and 5 replace (Y/La/Lu) and Al in (Y/La/Lu)₃Al₅O₁₂ respectively, and Zr—Mg replace Al—Al in (Y/La/Lu)₃Al₅O₁₂; and
the third class is that a small number of Zr serving as a charge compensating agent occupies the site A, and for example, in a patent document 6, Zr⁴⁺ or Hf⁴⁺ is adopted to serve as a charge compensating agent replaced with a small number of elements.
Non-patent document 1: Anant A. Setlur, William J. Heward, Yan Gao, Alok M. Srivastava, R. Gopi Chandran, and Madras V. Shankar, Chem. Mater., 2006, 18(14):3314-3322;
Non-patent document 2: S. Geller, Materials Research Bulletin, 1972, 7(11):1219-1224;
Patent document 1: U.S. Pat. No. 5,998,925B;
Patent document 2: U.S. Pat. No. 7,189,340B;
Patent document 3: CN 103509555 A;
Patent document 4: CN 103703102 A;
Patent document 5: CN 101760197 A; and
Patent document 6: CN 101323784 A.

### SUMMARY

The application is intended to provide a fluorescent powder which can be effectively excited by ultraviolet light or blue light to emit light, a preparation method therefor, and a light emitting device, an image display device and an illumination device comprising the fluorescent powder.

To this end, the application adopts the technical solution as follows.

The application provides a fluorescent powder and the fluorescent powder has a garnet crystal structure. A chemical formula thereof is expressed as: (M¹ₐ₋ₓM²ₓ)Zr_{b}M³_{c}O_{d}, wherein M¹ is one or two elements selected from Sr, Ca, La, Y, Lu and Gd, Ca or Sr being necessary; M² is one or two elements selected from Ce, Pr, Sm, Eu, Tb and Dy, Ce being necessary; and M³ is at least one element selected from Ga, Si, and Ge, Ga being necessary. 2.8≦a≦3.2, 1.9≦b≦2.1, 2.8≦c≦3.2, 11.8≦d≦12.2, and 0.002≦x≦0.6. Furthermore, 2.9≦a≦3.1, 1.9≦b≦2.0, 2.9≦c≦3.1, 11.9≦d≦12.1, and 0.02≦x≦0.4, preferably. Furthermore, a=3.0, b=2.0, c=3.0, and d=12.0, preferably.

The garnet structure refers to a crystal structure which belongs to a cubic system and has an Ia-3d space group, the general formula thereof is A₃B₂(XO₄)₃, where A, B and X usually refer to octa-coordination, hexa-coordination, and tetra-coordination; and B and an adjacent atom O form an octahedron usually, and X and the adjacent atom O form a tetrahedron usually. In the fluorescent powder, M¹ and M² occupy the site A, Zr occupies the site B of the hexa-coordination, M³ occupies the site X, and it may be proved by refinement of an X-powder ray diffraction pattern (it is illustrated with refinement of an X-powder ray diffraction pattern of (Ca₂Y_{0.94},Ce_{0.06})Zr₂Ga₃O₁₂, the refinement range is 10°≦2θ≦100°, a target material used by a diffractometer is a Co target, λ=0.178892 nm, and an initial model adopted for refinement is a typical garnet structure compound Y₃Al₅O₁₂; a refinement result is that a crystal system, a space group, crystal cell parameters and refinement residual factors are shown in Table 1; structural information such as atom coordinates, site occupancy ratios and temperature factors are shown in Table 2; a data fitting chart is shown in FIG. 7).

TABLE 1
Crystal system, space group, crystal cell parameters and
refinement residual factors of (Ca₂Y_{0.94},Ce_{0.06})Zr₂Ga₃O₁₂

| | |
|---|---|
| Molecular formula | (Ca₂Y_{0.94},Ce_{0.06})Zr₂Ga₃O₁₂ |
| Crystal system | Cubic system |
| Space group | Ia-3d |

Crystal cell parameters:

| | |
|---|---|
| a = b = c (Å) | 12.6316(3) |
| α = β = γ (deg) | 90 |
| V (Å³) | 2015.48(0) |
| Z | 8 |

Residual factors:

| | |
|---|---|
| Rₚ (%) | 8.32 |
| R_{wp} (%) | 11.6 |
| x² | 3.18 |

TABLE 2
Structural information such as atom coordinates, site occupancy
ratios and temperature factors of (Ca₂Y_{0.94}, Ce_{0.06})Zr₂Ga₃O₁₂

| | | | | | Site | |
|---|---|---|---|---|---|---|
| | | Atom position | | | occupancy | Temperature |
| Atom | Site | x | y | z | ratio | factor |
| Ca | 24c | 0.12500 | 0.00000 | 0.25000 | 0.16667 | 0.16903 |
| Ce | 24 | 0.12500 | 0.00000 | 0.25000 | 0.00500 | 0.16903 |
| Y | 24c | 0.12500 | 0.00000 | 0.25000 | 0.07833 | 0.16903 |
| Zr | 16a | 0.00000 | 0.00000 | 0.00000 | 0.16667 | 0.01778 |
| Ga | 24d | 0.37500 | 0.00000 | 0.25000 | 0.25000 | 0.13025 |
| O | 96h | 0.97016 | 0.05468 | 0.15353 | 1.00000 | 0.11939 |

In the fluorescent powder, Zr independently occupies the site B of the hexa-coordination, which is intended to obtain an emission wavelength shorter than YAG. Because the ion radius (0.72 Å) of Zr⁴⁺ is larger than the ion radius (0.535 Å) of Al³⁺, doping of the site B with a large-radius ion causes crystal cell volume expansion, and can weaken the crystal field where Ce³⁺ is placed, thereby reducing the 5d energy level splitting degree and realizing short-wavelength emission. Moreover, B is Zr independently, the ion radius difference of the site B can be reduced, and the lattice stress is reduced, such that the garnet structure is more stable.

The above structure refinement result shows that in the fluorescent powder of the application, Zr occupies the site B in the garnet structure. Therefore, the application eliminates relevancy to patent documents 3 and 6. The main difference between a patent document 5 and the application lies in that: Zr and an equal number of Mg or Zn are introduced to the site B at the same time in the patent document 5, and the site A only comprises trivalent rare-earth elements; however, the site B in the application only has Zr, and the site A must comprise bivalent alkaline-earth metal elements. In addition, the main difference between a patent document 4 and the application lies in that: the patent document 4 must comprise Al, and the synthetic temperature is higher than 1,500° C.; however, the application does not comprise Al but must comprise Ga, the synthetic temperature is lower than 1,400° C., and the application further includes: introducing bivalent metal elements (such as Ca and Sr) and tetravalent metal elements (such as Si and Ge) to the sites A and X respectively to further reduce the usage of rare-earth elements in the site A.

In the fluorescent powder, an atom number ratio m of (Ca+Sr) to M¹ is: 2/3≦m≦1. Setting of this range is intended to reduce the usage of rare-earth elements and meet molecular charge balance.

In the fluorescent powder, an atom number ratio n of Ce to M² is: 0.8≦n≦1. Setting of this range is intended to emphasize a principal role of Ce³⁺ as an activating agent, so as to obtain fluorescent powder having excellent light emitting performance.

In the fluorescent powder, an atom number ratio k of Ga to M³ is: 2/3≦k≦1. Setting of this range is intended to stabilize a garnet phase. Since the ion radius and charge differences of Si, Ge and Ga are large, Ga is controlled to exceed 2/3, and fluorescent powder having a stable garnet structure can be obtained.

In the fluorescent powder, Si and Ge are introduced into M³ to be capable of replacing part of Ga and reducing the usage of rare-earth elements in M¹, but the introduction amount does not exceed ⅓ of the total number of M³ atoms, which plays a role in enhancing ultraviolet and near-ultraviolet excitation and realizing the continuous adjustability of emission wavelengths.

In a word, setting of the ranges contributes to obtaining a stable garnet structure phase and fluorescent powder having excellent light emitting performance.

Preferably, in the fluorescent powder having a garnet structure of the application, M¹ comprises Ca or Sr preferably. The preference solution may reduce the size difference of ions in the same site, thereby reducing the lattice stress, and contributing to stabilization of the garnet structure.

More preferably, in the fluorescent powder having a garnet structure of the application, M¹ in the fluorescent powder comprises Ca preferably. Since the radius of Ca ions and rare-earth ions are close and well match a light emitting centre M², and a fluorescent powder having a stable structure and better light emitting performance can be obtained favourably.

In the fluorescent powder, parameters a, b, c and d are preferred as: a:b:c:d=3:2:3:12. Preference of the parameters in such ratio contributes to stabilization of a garnet phase and completeness of crystallization.

A preparation method for the fluorescent powder may include the steps as follows.
(1) serving compounds corresponding to M¹, M², M³ and Zr as raw materials and egrounding and unifromly mixing the compounds;
(2) roasting a mixture obtained in Step (1) in a reducing atmosphere at high temperatures; and
(3) after-treating a roasted product obtained in Step (2), and the fluorescent powder is obtained.

In Step (1), the compounds corresponding to the raw materials M¹, M², M³ and Zr includes oxides, carbonates, oxalates and nitrates.

In Step (2), high-temperature roasting is performed for one or several times, the roasting temperature ranges from 1,100° C. to 1400° C. at each time, and roasting lasts for 0.5 h to 20 h at each time.

In Step (3), after-treatment includes crushing, grinding or/and classifying.

In a word, the fluorescent powder involved in the application has excellent light emitting performance, and can realize emission from blue light to yellow-green light wave bands under the excitation of ultraviolet, near-ultraviolet and short-wavelength blue light by adjusting matrix components.

In addition, the application also provides a light emitting device. The light emitting device includes a light source and fluorescent powder, and at least one kind of fluorescent powder may be selected from the abovementioned fluorescent powder and the fluorescent powder prepared using the abovementioned preparation method.

Finally, the application also provides an image display device and an illumination device, wherein the image display device and the illumination device include the abovementioned light emitting device.

The application has the advantages as follows:
The fluorescent powder involved in the application has a wide effective excitation range, is suitable for being excited by ultraviolet, near-ultraviolet and short-wavelength blue light, and is high in applicability.
The fluorescent powder involved in the application can emit blue light-yellow green light under the excitation of ultraviolet, near-ultraviolet and short-wavelength blue light, and is high in light emitting efficiency.
The fluorescent powder of the application has a garnet structure, and the physical and chemical properties are very stable.
The synthetic temperature of the fluorescent powder involved in the application is low, the preparation process is simple, special reaction equipment is not needed, and industrialized production is convenient.

### BRIEF DESCRIPTION OF THE DRAWINGS

The drawings of the specification, forming a part of the application, are intended to provide further understanding of the application. The schematic embodiments and illustrations of the application are intended to explain the application, and do not form improper limits to the application. In the drawings:

FIG. 1 is an X-powder diffraction diagram of (Ca₂La_{0.96},Ce_{0.04})Zr₂Ga₃O₁₂;

FIG. 2 is an excitation spectrum diagram of (Ca₂La_{0.96},Ce_{0.04})Zr₂Ga₃O₁₂;

FIG. 3 is an emission spectrum diagram of (Ca₂La_{0.96},Ce_{0.04})Zr₂Ga₃O₁₂;

FIG. 4 is an X-powder diffraction diagram of (Ca_{2.91},Ce_{0.06})Zr₂(Ga₂Ge)O₁₂;

FIG. 5 is an excitation spectrum diagram of (Ca_{2.91},Ce_{0.06})Zr₂(Ga₂Ge)O₁₂;

FIG. 6 is an emission spectrum diagram of (Ca_{2.91},Ce_{0.06})Zr₂(Ga₂Ge)O₁₂; and

FIG. 7 is an X-powder diffraction refinement pattern of (Ca₂Y_{0.94}, Ce_{0.06})Zr₂Ga₃O₁₂.

### DETAILED DESCRIPTION OF THE EMBODIMENTS

The following further illustrations of the embodiments for fluorescent powder of the application and a preparation method thereof will contribute to further understanding of the application. A protective range of the application is not limited by these embodiments, and the protective range thereof is decided by the claims.

Comparing Sample

0.2 mol of CaCO₃, 0.05 ml of La₂O₃, 0.2 mol of ZrO₂ and 0.15 mol of Ga₂O₃ are weighed according to a chemical formula (Ca₂La)Zr₂Ga₃O₁₂. After these raw materials are fully ground and uniformly mixed, an obtained mixture is roasted for 4 h at the temperature of 1,350° C. in a CO atmosphere. A roasted product is after-treated, including crushing, classifying, washing, drying, sieving and the like to obtain a compound having a composition: (Ca₂La)Zr₂Ga₃O₁₂. A sample is extracted for spectrum test, an emission spectrum being not seen under the excitation of ultraviolet and blue-light areas. The relative luminous intensity under the excitation of 420 nm is 0, as shown in Table 3.

### Embodiment 1

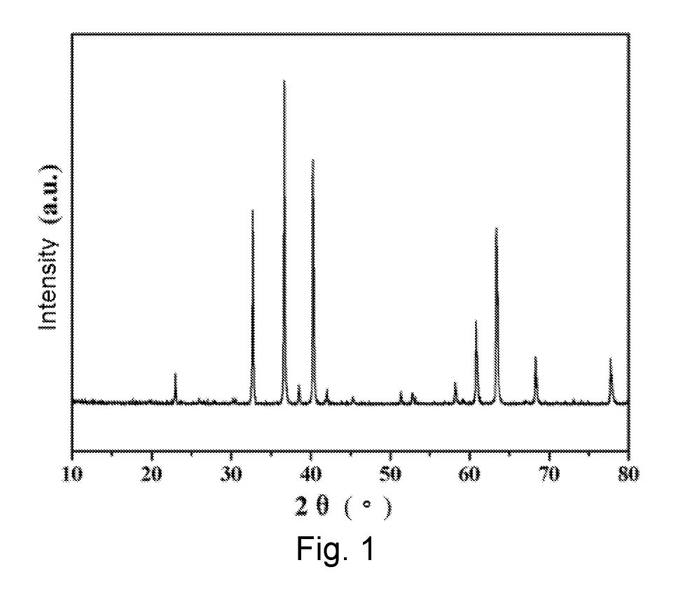

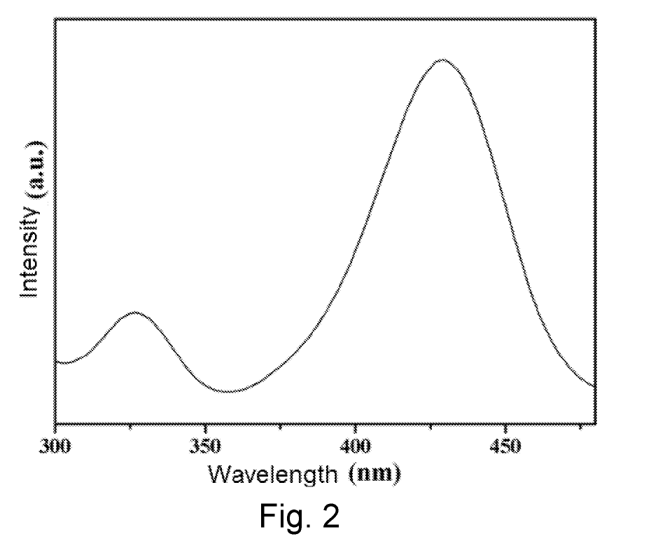

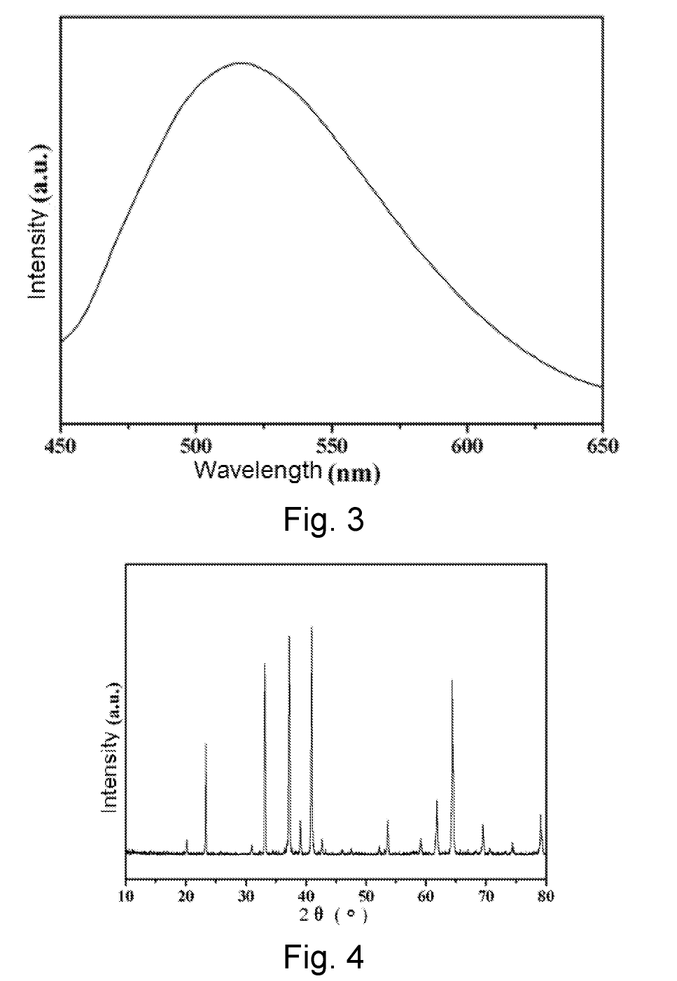

0.2 mol of CaCO₃, 0.048 ml of La₂O₃, 0.2 mol of ZrO₂, 0.15 mol of Ga₂O₃ and 0.004 mol of CeO₂ are weighed according to a chemical formula (Ca₂La_{0.96},Ce_{0.04})Zr₂Ga₃O₁₂ of fluorescent powder. After these raw materials are fully ground and uniformly mixed, an obtained mixture is roasted for 4 h at the temperature of 1,350° C. in a CO atmosphere. A roasted product is after-treated, including crushing, classifying, washing, drying, sieving and the like to obtain fluorescent powder having a composition: (Ca₂La_{0.96},Ce_{0.04})Zr₂Ga₃O₁₂. An X-powder diffraction diagram (Co target, λ=0.178892 nm) thereof is shown in FIG. 1. An excitation spectrum (515 nm monitoring) and an emission spectrum (420 nm excitation) thereof are shown in FIG. 2 and FIG. 3. From the drawings, it can be obtained that an excitation wavelength range covers 280 to 480 nm, under the 420 nm excitation, the peak wavelength of the emission spectrum is 515 nm, and the relative luminous intensity is shown in Table 3.

### Embodiment 2

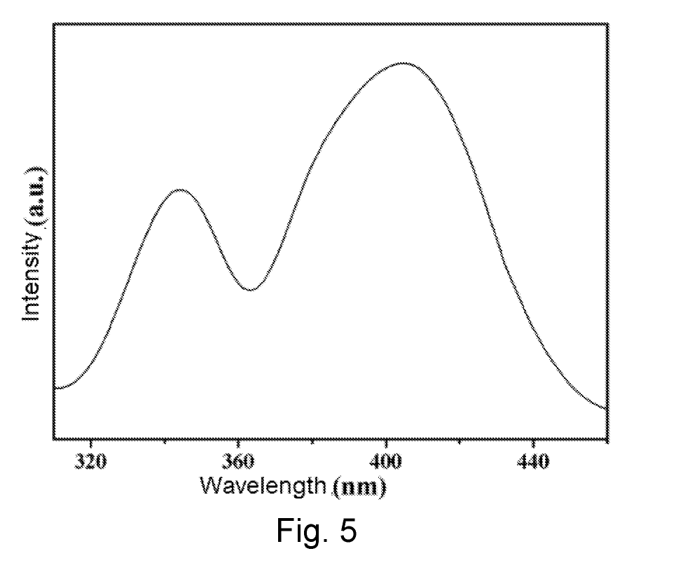

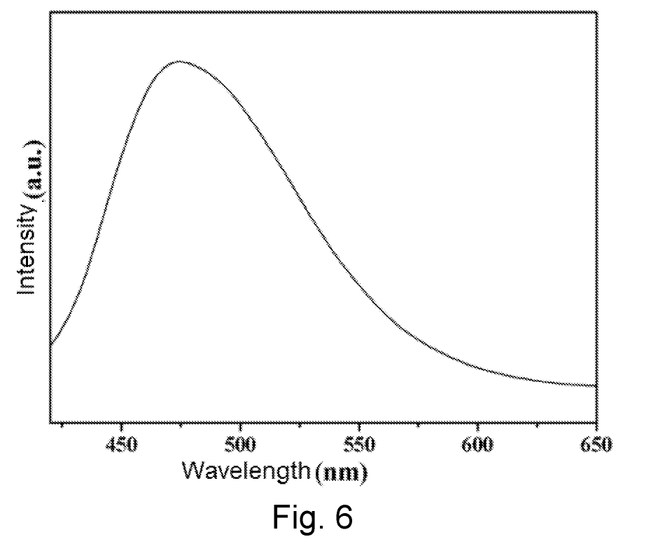

0.291 mol of CaCO₃, 0.2 mol of ZrO₂, 0.1 mol of GeO₂, 0.1 mol of Ga₂O₃ and 0.006 mol of CeO₂ are weighed according to a chemical formula (Ca_{2.91},Ce_{0.06})Zr₂(Ga₂Ge)O₁₂ of fluorescent powder. After these raw materials are fully ground and uniformly mixed, an obtained mixture is roasted for 8 h at the temperature of 1,320° C. in a CO atmosphere. A roasted product is after-treated, including crushing, classifying, washing, drying, sieving and the like to obtain fluorescent powder having a composition: (Ca_{2.91},Ce_{0.06})Zr₂(Ga₂Ge)O₁₂. An X-powder diffraction diagram (Co target, λ=0.178892 nm) thereof is shown in FIG. 4. An excitation spectrum (475 nm monitoring) and an emission spectrum (420 nm excitation) thereof are shown in FIG. 5 and FIG. 6. From the drawings, it can be obtained that an excitation wavelength range covers 280 to 440 nm, under the 420 nm excitation, the peak wavelength of the emission spectrum is 475 nm, and the relative luminous intensity is shown in Table 3.

### Embodiment 3

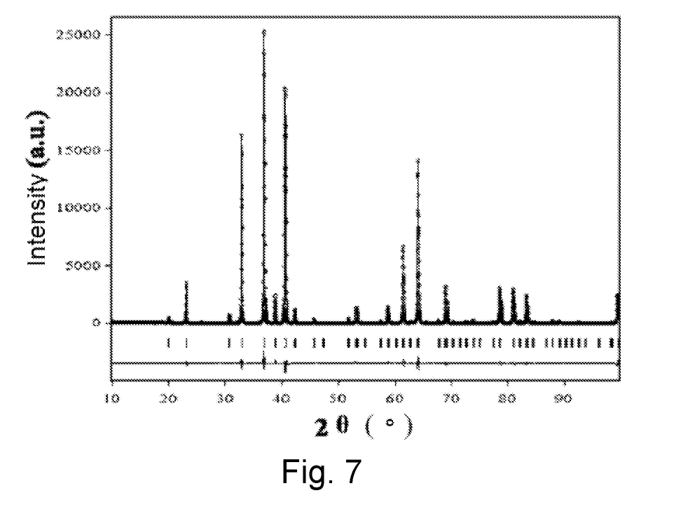

0.2 mol of CaCO₃, 0.2 mol of ZrO₂, 0.047 mol of Y₂O₃, 0.15 mol of Ga₂O₃ and 0.006 mol of Ce(NO₃)₃ are weighed according to a chemical formula (Ca₂Y_{0.94},Ce_{0.06})Zr₂Ga₃O₁₂ of fluorescent powder. After these raw materials are fully ground and uniformly mixed, an obtained mixture is roasted for 6 h at the temperature of 1,360° C. in an H₂/N₂ mixed atmosphere. A roasted product is after-treated, including crushing, classifying, washing, drying, sieving and the like to obtain fluorescent powder having a composition: (Ca₂Y_{0.94},Ce_{0.06})Zr₂Ga₃O₁₂. X-powder ray diffraction refinement fitting parameters thereof are shown in Table 1 and Table 2. Fitting of a pattern is shown in FIG. 7. An excitation wavelength range covers 280 to 480 nm, under the 420 nm excitation, the peak wavelength of the emission spectrum is 512 nm, and the relative luminous intensity is shown in Table 3.

### Embodiment 4

0.2 mol of CaCO₃, 0.2 mol of ZrO₂, 0.046 mol of Lu₂O₃, 0.15 mol of Ga₂O₃ and 0.008 mol of CeO₂ are weighed according to a chemical formula (Ca₂Lu_{0.92},Ce_{0.08})Zr₂Ga₃O₁₂ of fluorescent powder. After these raw materials are fully ground and uniformly mixed, an obtained mixture is roasted for 4 h at the temperature of 1,100° C. in air. A roasted product is crushed and then secondarily roasted for 6 h at the sintering temperature of 1,350° C. in a CO atmosphere. A secondarily roasted product is after-treated, including crushing, classifying, washing, drying, sieving and the like to obtain fluorescent powder having a composition: (Ca₂Lu_{0.92},Ce_{0.08})Zr₂Ga₃O₁₂. An excitation wavelength range covers 280 to 480 nm, under the 420 nm excitation, the peak wavelength of the emission spectrum is 502 nm, and the relative luminous intensity is shown in Table 3.

### Embodiment 5

0.2 mol of CaCO₃, 0.045 mol of Gd₂O₃, 0.2 mol of ZrO₂, 0.15 mol of Ga₂O₃ and 0.01 mol of CeO₂ are weighed according to a chemical formula (Ca₂Gd_{0.9},Ce_{0.1})Zr₂Ga₃O₁₂ of fluorescent powder. After these raw materials are fully ground and uniformly mixed, an obtained mixture is roasted for 6 h at the temperature of 1,400° C. in an H₂/N₂ mixed atmosphere. A roasted product is after-treated, including crushing, classifying, washing, drying, sieving and the like to obtain fluorescent powder having a composition: (Ca₂Gd_{0.9},Ce_{0.1})Zr₂Ga₃O₁₂. An excitation wavelength range covers 280 to 480 nm, under the 420 nm excitation, the peak wavelength of the emission spectrum is 514 nm, and the relative luminous intensity is shown in Table 3.

### Embodiment 6

0.275 mol of CaCO₃, 0.01 mol of SrCO₃, 0.2 mol of ZrO₂, 0.02 mol of SiO₂, 0.1 mol of Ga₂O₃, 0.08 mol of GeO₂ and 0.01 mol of CeO₂ are weighed according to a chemical formula (Ca_{2.75}Sr_{0.1},Ce_{0.1})Zr₂(Ga₂Ge_{0.8}Si_{0.2})O₁₂ of fluorescent powder. After these raw materials are fully ground and uniformly mixed, an obtained mixture is roasted for 0.5 h at the temperature of 1,200° C. in air. A primarily roasted product is crushed and then secondarily roasted for 6 h at the sintering temperature of 1,320° C. in a CO atmosphere. A secondarily roasted product is after-treated, including crushing, classifying, washing, drying, sieving and the like to obtain fluorescent powder having a composition: (Ca_{2.75}Sr_{0.1},Ce_{0.1})Zr₂(Ga₂Ge_{0.8}Si_{0.2})O₁₂. An excitation wavelength range covers 280 to 460 nm, under the 420 nm excitation, the peak wavelength of the emission spectrum is 482 nm, and the relative luminous intensity is shown in Table 3.

### Embodiment 7

0.25 mol of CaCO₃, 0.0225 mol of Lu₂O₃, 0.2 mol of ZrO₂, 0.05 mol of SiO₂, 0.125 mol of Ga₂O₃, 0.0005 mol of Eu₂O₃ and 0.004 mol of CeO₂ are weighed according to a chemical formula (Ca_{2.5}Lu_{0.45},Ce_{0.04}Eu_{0.01})Zr₂(Ga_{2.5}Si_{0.5})O₁₂ of fluorescent powder. After these raw materials are fully ground and uniformly mixed, an obtained mixture is roasted for 8 h at the temperature of 1,400° C. in a CO atmosphere. A roasted product is after-treated, including crushing, classifying, washing, drying, sieving and the like to obtain fluorescent powder having a composition: (Ca_{2.5}Lu_{0.45},Ce_{0.04}Eu_{0.01})Zr₂(Ga_{2.5}Si_{0.5})O₁₂. An excitation wavelength range covers 280 to 480 nm, under the 420 nm excitation, the peak wavelength of the emission spectrum is 493 nm, and the relative luminous intensity is shown in Table 3.

### Embodiment 8

0.2997 mol of CaCO₃, 0.2 mol of ZrO₂, 0.1 mol of SiO₂, 0.1 mol of Ga₂O₃ and 0.0002 mol of CeO₂ are weighed according to a chemical formula (Ca_{2.997},Ce_{0.002})Zr₂(Ga₂Si)O₁₂ of fluorescent powder. After these raw materials are fully ground and uniformly mixed, an obtained mixture is roasted for 4 h at the temperature of 1,380° C. in a CO atmosphere. A roasted product is after-treated, including crushing, classifying, washing, drying, sieving and the like to obtain fluorescent powder having a composition: (Ca_{2.997},Ce_{0.002})Zr₂(Ga₂Si)O₁₂. An excitation wavelength range covers 280 to 450 nm, under the 420 nm excitation, the peak wavelength of the emission spectrum is 487 nm, and the relative luminous intensity is shown in Table 3.

### Embodiment 9

0.24 mol of CaCO₃, 0.19 mol of ZrO₂, 0.0375 mol of Y₂O₃, 0.14 mol of Ga₂O₃, 0.004 mol of CeO₂ and 0.00017 mol of Pr₆O₁₁ are weighed according to a chemical formula (Ca_{2.4}Y_{0.75},Ce_{0.04}Pr_{0.01})Zr_{1.9}Ga_{2.8}O_{11.8} of fluorescent powder. After these raw materials are fully ground and uniformly mixed, carbon powder is added, and an obtained mixture is roasted for 15 h at the temperature of 1,350° C. A roasted product is after-treated, including crushing, classifying, washing, drying, sieving and the like to obtain fluorescent powder having a composition: (Ca_{2.4}Y_{0.75},Ce_{0.04}Pr_{0.01})Zr_{1.9}Ga_{2.8}O_{11.8}. An excitation wavelength range covers 280 to 480 nm, under the 420 nm excitation, the peak wavelength of the emission spectrum is 510 nm, and the relative luminous intensity is shown in Table 3.

### Embodiment 10

0.2 mol of SrCO₃, 0.035 mol of Gd₂O₃, 0.21 mol of ZrO₂, 0.16 mol of Ga₂O₃, 0.008 mol of CeO₂ and 0.001 mol of Dy₂O₃ are weighed according to a chemical formula (Sr₂Gd_{0.7},Ce_{0.08}Dy_{0.02})Zr_{2.1}Ga_{3.2}O_{12.2} of fluorescent powder. After these raw materials are fully ground and uniformly mixed, an obtained mixture is roasted for 20 h at the temperature of 1,400° C. in a CO atmosphere. A roasted product is after-treated, including crushing, classifying, washing, drying, sieving and the like to obtain fluorescent powder having a composition: (Sr₂Gd_{0.7},Ce_{0.08}Dy_{0.02})Zr_{2.1}Ga_{3.2}O_{12.2}. An excitation wavelength range covers 280 to 480 nm, under the 420 nm excitation, the peak wavelength of the emission spectrum is 526 nm, and the relative luminous intensity is shown in Table 3.

### Embodiment 11

0.294 mol of SrCO₃, 0.1 mol of SiO₂, 0.2 mol of ZrO₂, 0.1 mol of Ga₂O₃ and 0.004 mol of CeO₂ are weighed according to a chemical formula (Sr_{2.94},Ce_{0.04})Zr₂(Ga₂Si)O₁₂ of fluorescent powder. After these raw materials are fully ground and uniformly mixed, an obtained mixture is roasted for 6 h at the temperature of 1,300° C. in air. A roasted product is crushed and then secondarily roasted for 10 h at the sintering temperature of 1,400° C. in a CO/N₂ atmosphere. A secondarily roasted product is after-treated, including crushing, classifying, washing, drying, sieving and the like to obtain fluorescent powder having a composition: (Sr_{2.94},Ce_{0.04})Zr₂(Ga₂Si)O₁₂. An excitation wavelength range covers 280 to 480 nm, under the 420 nm excitation, the peak wavelength of the emission spectrum is 494 nm, and the relative luminous intensity is shown in Table 3.

### Embodiment 12

0.2 mol of SrCO₃, 0.2 mol of ZrO₂, 0.0475 mol of La₂O₃, 0.15 mol of Ga₂O₃ and 0.005 mol of CeO₂ are weighed according to a chemical formula (Sr₂La_{0.95},Ce_{0.05})Zr₂Ga₃O₁₂ of fluorescent powder. After these raw materials are fully ground and uniformly mixed, an obtained mixture is roasted for 6 h at the temperature of 1,200° C. in air. A roasted product is crushed and then secondarily roasted for 2 h at the sintering temperature of 1,370° C. in an H₂/N₂ atmosphere. A secondarily roasted product is after-treated, including crushing, classifying, washing, drying, sieving and the like to obtain fluorescent powder having a composition: (Sr₂La_{0.95},Ce_{0.005})Zr₂Ga₃O₁₂. An excitation wavelength range covers 280 to 480 nm, under the 420 nm excitation, the peak wavelength of the emission spectrum is 535 nm, and the relative luminous intensity is shown in Table 3.

### Embodiment 13

0.2 mol of CaCO₃, 0.2 mol of ZrO₂, 0.02 mol of Y₂O₃, 0.15 mol of Ga₂O₃, 0.05 mol of CeO₂ and 0.0025 mol of Tb₄O₇ are weighed according to a chemical formula (Ca₂Y_{0.4},Ce_{0.5}Tb_{0.1})Zr₂Ga₃O₁₂ of fluorescent powder. After these raw materials are fully ground and uniformly mixed, an obtained mixture is roasted for 4 h at the temperature of 1,350° C. in a CO atmosphere. A roasted product is after-treated, including crushing, classifying, washing, drying, sieving and the like to obtain fluorescent powder having a composition: (Ca₂Y_{0.4},Ce_{0.5}Tb_{0.1})Zr₂Ga₃O₁₂. An excitation wavelength range covers 280 to 450 nm, under the 420 nm excitation, the peak wavelength of the emission spectrum is 542 nm, and the relative luminous intensity is shown in Table 3.

### Embodiment 14

0.28 mol of CaCO₃, 0.2 mol of ZrO₂, 0.08 mol of SiO₂, 0.008 mol of Gd₂O₃, 0.11 mol of Ga₂O₃ and 0.004 mol of CeO₂ are weighed according to a chemical formula (Ca_{2.8}Gd_{0.16},Ce_{0.04})Zr₂(Ga_{2.2}Si_{0.8})O₁₂ of fluorescent powder. After these raw materials are fully ground and uniformly mixed, an obtained mixture is roasted for 6 h at the temperature of 1,320° C. in a CO atmosphere. A roasted product is after-treated, including crushing, classifying, washing, drying, sieving and the like to obtain fluorescent powder having a composition: (Ca_{2.8}Gd_{0.16},Ce_{0.04})Zr₂(Ga_{2.2}Si_{0.8})O₁₂. An excitation wavelength range covers 280 to 450 nm, under the 420 nm excitation, the peak wavelength of the emission spectrum is 492 nm, and the relative luminous intensity is shown in Table 3.

### Embodiment 15

0.22 mol of SrCO₃, 0.2 mol of ZrO₂, 0.02 mol of SiO₂, 0.0365 mol of La₂O₃, 0.14 mol of Ga₂O₃, 0.005 mol of CeO₂ and 0.001 mol of Sm₂O₃ are weighed according to a chemical formula (Sr_{2.2}La_{0.73},Ce_{0.05}Sm_{0.02})Zr₂(Ga_{2.8}Si_{0.2})O₁₂ of fluorescent powder. After these raw materials are fully ground and uniformly mixed, an obtained mixture is roasted for 6 h at the temperature of 1,200° C. in air. A roasted product is crushed and then secondarily roasted for 2 h at the sintering temperature of 1,380° C. in an H₂/N₂ atmosphere. A secondarily roasted product is after-treated, including crushing, classifying, washing, drying, sieving and the like to obtain fluorescent powder having a composition: (Sr_{2.2}La_{0.73},Ce_{0.05}Sm_{0.02})Zr₂(Ga_{2.8}Si_{0.2})O₁₂. An excitation wavelength range covers 280 to 480 nm, under the 420 nm excitation, the peak wavelength of the emission spectrum is 524 nm, and the relative luminous intensity is shown in Table 3.

### Embodiment 16

Green fluorescent powder obtained in Embodiment 1 and red powder of K₂SiF₆:Mn are scattered in resin in a ratio of 7:1, and after being mixed, the slurry is coated on a 450 nm blue-light LED chip, solidified, welded to a circuit and sealed by the resin to obtain a light emitting device emitting white light, the chromaticity coordinate being (0.3885, 0.3692), the colour rendering index being 87.2, and the correlated colour temperature being 3624K.

### Embodiment 17

Blue fluorescent powder obtained in Embodiment 2, β-SiAlON:Eu green fluorescent powder and CaAlSiN₃:Eu red fluorescent powder are scattered in resin in a ratio of 3:6:1, and after being mixed, the slurry is coated on a 405 nm ultraviolet LED chip, solidified, welded to a circuit and sealed by the resin to obtain a light emitting device emitting white light, the chromaticity coordinate being (0.3963, 0.3785), and the colour reproduction range being 80% NTSC.

### Embodiment 18

Blue fluorescent powder obtained in Embodiment 7, green fluorescent powder obtained in Embodiment 13 and (Sr,Ca)₂Si₅N₈:Eu red fluorescent powder are scattered in resin in a ratio of 4:7:1, and after being mixed, the slurry is coated on a 405 nm ultraviolet LED chip, solidified, welded to a circuit and sealed by the resin to obtain a light emitting device emitting white light, the chromaticity coordinate being (0.3796, 0.3589), the colour rendering index being 85.6, and the correlated colour temperature being 4230K.

TABLE 3
Chemical formulae of comparing example and Embodiments 1-15, and
emission main peak position and relative luminous intensity under 420 nm excitation
(the luminous intensity of Ca₂La_{0.96}Zr₂Ga₃O₁₂:Ce_{0.04} is selected to be 100% under the
420 nm excitation)

| | | Emission | Relative |
|---|---|---|---|
| | | main peak | luminous |
| | Chemical formula of fluorescent | position | intensity |
| Serial number | powder | (nm) | (%) |
| Comparing | (Ca₂La)Zr₂Ga₃O₁₂ | Null | 0 |
| example | | | |
| Embodiment 1 | (Ca₂La_{0.96},Ce_{0.04})Zr₂Ga₃O₁₂ | 515 | 100 |
| Embodiment 2 | (Ca_{2.91},Ce_{0.06})Zr₂(Ga₂Ge)O₁₂ | 475 | 112 |
| Embodiment 3 | (Ca₂Y_{0.94},Ce_{0.06})Zr₂Ga₃O₁₂ | 512 | 105 |
| Embodiment 4 | (Ca₂Lu_{0.92},Ce_{0.08})Zr₂Ga₃O₁₂ | 502 | 101 |
| Embodiment 5 | (Ca₂Gd_{0.9},Ce_{0.1})Zr₂Ga₃O₁₂ | 514 | 102 |
| Embodiment 6 | (Ca_{2.75}Sr_{0.1},Ce_{0.1})Zr₂(Ga₂Ge_{0.8}Si_{0.2})O₁₂ | 482 | 95 |
| Embodiment 7 | (Ca_{2.5}Lu_{0.45},Ce_{0.04}Eu_{0.01})Zr₂(Ga_{2.5}Si_{0.5})O₁₂ | 493 | 107 |
| Embodiment 8 | (Ca_{2.997},Ce_{0.002})Zr₂(Ga₂Si)O₁₂ | 487 | 98 |
| Embodiment 9 | (Ca_{2.4}Y_{0.75},Ce_{0.04}Pr_{0.01})Zr_{1.9}Ga_{2.8}O_{11.8} | 510 | 102 |
| Embodiment 10 | (Sr₂Gd_{0.7},Ce_{0.08}Dy_{0.02})Zr_{2.1}Ga_{3.2}O_{12.2} | 526 | 96 |
| Embodiment 11 | (Sr_{2.94},Ce_{0.04})Zr₂(Ga₂Si)O₁₂ | 494 | 103 |
| Embodiment 12 | (Sr₂La_{0.95},Ce_{0.05})Zr₂Ga₃O₁₂ | 535 | 96 |
| Embodiment 13 | (Ca₂Y_{0.4},Ce_{0.5}Tb_{0.1})Zr₂Ga₃O_{12.} | 542 | 106 |
| Embodiment 14 | (Ca_{2.8}Gd_{0.16},Ce_{0.04})Zr₂(Ga_{2.2}Si_{0.8})O₁₂ | 492 | 102 |
| Embodiment 15 | (Sr_{2.2}La_{0.73},Ce_{0.05}Sm_{0.02})Zr₂(Ga_{2.8}Si_{0.2})O₁₂ | 524 | 97 |

1-14. (canceled)

15. A fluorescent powder, wherein the fluorescent powder has a garnet crystal structure, and a chemical formula of the fluorescent powder is expressed as: (M¹ₐ₋ₓM²ₓ)Zr_{b}M³_{c}O_{d}, wherein M¹ is one or two elements selected from Sr, Ca, La, Y, Lu and Gd, Ca or Sr being necessary; M² is one or two elements selected from Ce, Pr, Sm, Eu, Tb and Dy, Ce being necessary; M³ is at least one element selected from Ga, Si, and Ge, Ga being necessary; and 2.8≦a≦3.2, 1.9≦b≦2.1, 2.8≦c≦3.2, 11.8≦d≦12.2, and 0.002≦x≦0.6.

16. The fluorescent powder according to claim 15, wherein an atom number ratio m of (Ca+Sr) to M¹ is: 2/3≦m≦1.

17. The fluorescent powder according to claim 15, wherein an atom number ratio n of Ce to M² is: 0.8≦n≦1.

18. The fluorescent powder according to claim 17, wherein an atom number ratio k of Ga to M³ is: 2/3≦k≦1.

19. The fluorescent powder according to claim 15, wherein M¹ in the fluorescent powder comprises Ca.

20. The fluorescent powder according to claim 15, wherein a:b:c:d is 3:2:3:12.

21. The fluorescent powder according to claim 15, wherein
when M¹ comprises Ca, an atom number ratio m of Ca to M¹ is: 2/3≦m≦1; and
when M¹ comprises Sr and does not comprise Ca, an atom number ratio m of Sr to M¹ is: 2/3≦m≦1.

22. A method for preparing the fluorescent powder according to claim 15, comprising the following steps:
(1) serving compounds corresponding to M¹, M², M³ and Zr as raw materials and egrounding and unifromly mixing the compounds;
(2) roasting a mixture obtained in Step (1) in a reducing atmosphere at high temperatures; and
(3) after-treating a roasted product obtained in Step (2), and the fluorescent powder is obtained.

23. The method according to claim 22, wherein in Step (1), the compounds corresponding to M¹, M², M³ and Zr comprise oxides, carbonates, oxalates and nitrates.

24. The method according to claim 22, wherein in Step (2), the roasting is performed for one or several times, temperatures of the roasting range from 1,100° C.˜1,400° C. at each time, and the roasting lasts for 0.5 h to 20 h at each time.

25. The method according to claim 24, wherein in Step (3), the after-treating comprises crushing, grinding or/and classifying.

26. A light emitting device, comprising a light source and fluorescent powder, wherein at least one kind of fluorescent powder is selected from the fluorescent powder according to claim 15.

27. The fluorescent powder according to claim 16, wherein an atom number ratio n of Ce to M² is: 0.8≦n≦1.

28. The method according to claim 23, wherein in Step (2), the roasting is performed for one or several times, temperatures of the roasting range from 1,100° C.˜1,400° C. at each time, and the roasting lasts for 0.5 h to 20 h at each time.
